(19) United States
(12) Patent Application Publication
(10) Pub. No.: US 2026/0302718 A1
(43) Pub. Date: Oct. 1, 2026

(54) SEMICONDUCTOR DEVICE

(71) Applicant: NTT, Inc., Tokyo (JP)

(72) Inventors: Hayato Arai, Tokyo (JP); Wataru Kobayashi, Tokyo (JP)

(21) Appl. No.: 19/483,466

(22) PCT Filed: May 12, 2023
(86) PCT No.: PCT/JP2023/017892

§ 371 Date: Nov. 11, 2025

(51) Int. Cl. H01S 5/02; H01S 5/20; H01S 5/22

(52) U.S. Cl. CPC H01S 5/0208; H01S 5/2031; H01S 5/22

(57) ABSTRACT

A semiconductor device comprises a semi-insulating InP substrate, a p-type InP first lower semiconductor layer on the substrate, first and second optical active elements on respective substrate regions, and an optical waveguide between them. The first lower semiconductor layer includes a groove where the optical waveguide is disposed. The optical waveguide provides electrical isolation and optical connection between the optical active elements. The first optical active element includes the first lower semiconductor layer, a first active layer with ridge waveguide structure, an n-type InP upper semiconductor layer, a first n-electrode on the upper semiconductor layer, a first p-electrode on the first lower semiconductor layer where the first active layer is absent, and an embedding layer embedding the first active layer. The first p-electrode is positioned where the embedding layer is absent, with the first lower semiconductor layer having 400-1000 nm thickness.

### CROSS-REFERENCE TO RELATED APPLICATIONS

This application is a national phase entry of PCT Application No. PCT/JP2023/017892, filed on May 12, 2023, which application is hereby incorporated herein by reference.

### TECHNICAL FIELD

The present invention relates to a semiconductor device in which a plurality of optical active elements is integrated.

### BACKGROUND

In optical communication, a light source having a modulation function is used. For example, in optical communication with a relatively short transmission distance of 100 km or less, an electroabsorption-modulator integrated distributed feedback laser (EML) in which an electroabsorption-modulator and a DFB laser are integrated, is used.

In a conventional EML, a DFB laser that generates light as a carrier wave and an EA modulator that modulates the carrier wave are monolithically integrated on a single semiconductor substrate (Patent Literature 1, Patent Literature 2). In this configuration, the semiconductor substrate uses conductive polarity (mainly an n-polar InP substrate). Therefore, the electrical polarity of the substrate of the portion of each integrated element is inevitably short-circuited due to the structure. Therefore, during operation of the DFB laser and the EA modulator, the substrate is GND, a positive voltage is applied to the DFB laser unit, and a negative voltage is applied to the EA modulator. In this configuration, the EA modulator is driven by applying a single-phase modulation signal. For example, one of the electrodes of the EA modulator is connected to GND to perform single-phase driving.

### CITATION LIST

### Patent Literature

Patent Literature 1: JP 5823920 B2
Patent Literature 2: JP 6717733 B2

### Non Patent Literature

Non Patent Literature 1: W. Kobayashi et al., “Design and Fabrication of Wide Wavelength Range 25.8-Gb/S, 1.3-μM, Push-Pull-Driven DMLs”, Journal of Lightwave Technology, vol. 32, no. 1, pp. 3-9, 2014.

### SUMMARY

### Technical Problem

Meanwhile, in order to maximize the characteristics of the EA modulator, it is desirable to perform differential driving. This is because differential driving has effects of improving the S/N of the optical waveform by suppressing common mode noise and halving the modulation amplitude voltage applied to each signal line (Non Patent Literature 1). However, in the conventional structure, since the substrate side is short-circuited, the DFB laser is single-phase driven, and the EA modulator cannot be differentially driven. As described above, in the conventional techniques, there is a problem that two monolithically integrated optical active elements cannot be driven by respective different methods.

The present invention has been made to solve the above problems, and an object of the present invention is to drive the two monolithically integrated optical active elements by respective different methods.

### Solution to Problem

A semiconductor device according to the present invention includes a substrate made of semi-insulating InP, a first optical active element formed on the substrate, a second optical active element formed on the substrate, and an optical waveguide disposed between the first optical active element and the second optical active element, functioning as an electrical isolation portion between the first optical active element and the second optical active element, and optically connecting the first optical active element and the second optical active element with each other, in which the first optical active element includes a first lower semiconductor layer made of p-type InP formed on the substrate, a first active layer formed on the first lower semiconductor layer and having a ridge waveguide structure, an upper semiconductor layer made of n-type InP formed on the first active layer, a first n-electrode formed on the upper semiconductor layer, and a first p-electrode formed on the first lower semiconductor layer in a region where the first active layer is not formed, the second optical active element includes a second active layer formed on the first lower semiconductor layer and having a ridge waveguide structure, the upper semiconductor layer formed on the second active layer, a second n-electrode formed on the upper semiconductor layer, and a second p-electrode formed on the first lower semiconductor layer in a region where the second active layer is not formed, the optical waveguide includes a second lower semiconductor layer made of semi-insulating or undoped InP formed in a groove formed in the first lower semiconductor layer in the region of the optical waveguide, a third active layer formed on the second lower semiconductor layer and having a ridge waveguide structure, and the upper semiconductor layer formed on the third active layer, the first lower semiconductor layer in a region where the second active layer is not formed is made thinner than the first lower semiconductor layer in a region where the second active layer is formed, an embedding layer embedding the first active layer is formed on the first lower semiconductor layer, the first p-electrode is formed at a position where the embedding layer is removed, and the first lower semiconductor layer where the first p-electrode is formed has a thickness from 400 nm to 1000 nm.

### Advantageous Effects of Invention

As described above, according to the present invention, the thickness of the region where the first n-electrode of the first lower semiconductor layer made of p-type InP below the first active layer is formed is from 400 nm to 1000 nm, and thus the two monolithically integrated optical active elements can be driven by respective different methods without causing deterioration in optical output characteristics and optical modulation characteristics.

### BRIEF DESCRIPTION OF THE DRAWINGS

FIG. 1A is a cross-sectional view illustrating a configuration of a semiconductor device according to an embodiment of the present invention.

FIG. 1B is a cross-sectional view illustrating a partial configuration of the semiconductor device according to the embodiment of the present invention.

FIG. 1C is a cross-sectional view illustrating part of the configuration of the semiconductor device according to the embodiment of the present invention.

FIG. 1D is a cross-sectional view illustrating part of the configuration of the semiconductor device according to the embodiment of the present invention.

FIG. 2A is a characteristic diagram showing calculation results of a relationship between a resistance value R of a first lower semiconductor layer 121 and a distance d between a first p-electrode 125 and a first active layer 122 when a length L of the first lower semiconductor layer 121 in a waveguide direction is 300 μm, and a thickness t under the first p-electrode 125 is 0.4 μm, 0.6 μm, and 0.8 μm.

FIG. 2B is a characteristic diagram showing calculation results of a relationship between a resistance value of an upper semiconductor layer 105 and a length L on a third active layer 142 when a waveguide width is 2 μm and a thickness of a portion formed on the third active layer 142 in the upper semiconductor layer 105 is 0.2 μm, 0.4 μm, and 0.6 μm.

FIG. 3A is a cross-sectional view illustrating a state of the semiconductor device in an intermediate step for describing a method for manufacturing the semiconductor device according to the embodiment of the present invention.

FIG. 3B is a cross-sectional view illustrating a state of the semiconductor device in an intermediate step for describing a method for manufacturing the semiconductor device according to the embodiment of the present invention.

FIG. 3C is a cross-sectional view illustrating a state of the semiconductor device in an intermediate step for describing a method for manufacturing the semiconductor device according to the embodiment of the present invention.

FIG. 3D is a cross-sectional view illustrating a state of the semiconductor device in an intermediate step for describing a method for manufacturing the semiconductor device according to the embodiment of the present invention.

FIG. 3E is a cross-sectional view illustrating a state of the semiconductor device in an intermediate step for describing a method for manufacturing the semiconductor device according to the embodiment of the present invention.

FIG. 3F is a cross-sectional view illustrating a state of the semiconductor device in an intermediate step for describing a method for manufacturing the semiconductor device according to the embodiment of the present invention.

FIG. 3G is a cross-sectional view illustrating a state of the semiconductor device in an intermediate step for describing a method for manufacturing the semiconductor device according to the embodiment of the present invention.

FIG. 3H is a cross-sectional view illustrating a state of the semiconductor device in an intermediate step for describing the method for manufacturing the semiconductor device according to the embodiment of the present invention.

FIG. 3I is a cross-sectional view illustrating a state of the semiconductor device in an intermediate step for describing the method for manufacturing the semiconductor device according to the embodiment of the present invention.

FIG. 3J is a cross-sectional view illustrating a state of the semiconductor device in an intermediate step for explaining the method for manufacturing the semiconductor device according to the embodiment of the present invention.

FIG. 3K is a cross-sectional view illustrating a state of the semiconductor device in an intermediate step for explaining the method for manufacturing the semiconductor device according to the embodiment of the present invention.

FIG. 3L is a cross-sectional view illustrating a state of the semiconductor device in an intermediate step for describing a method for manufacturing the semiconductor device according to the embodiment of the present invention.

FIG. 3M is a cross-sectional view illustrating a state of the semiconductor device in an intermediate step for describing a method for manufacturing the semiconductor device according to the embodiment of the present invention.

### DETAILED DESCRIPTION OF ILLUSTRATIVE EMBODIMENTS

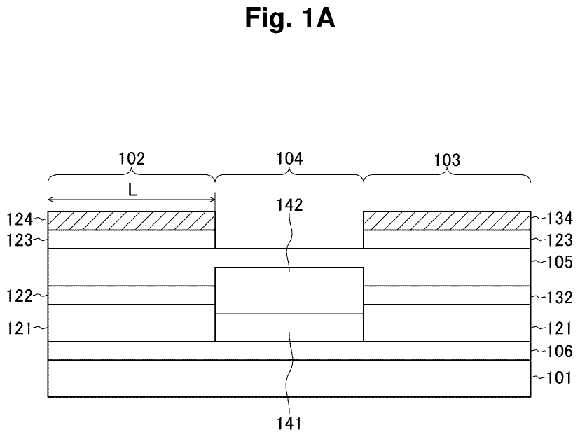

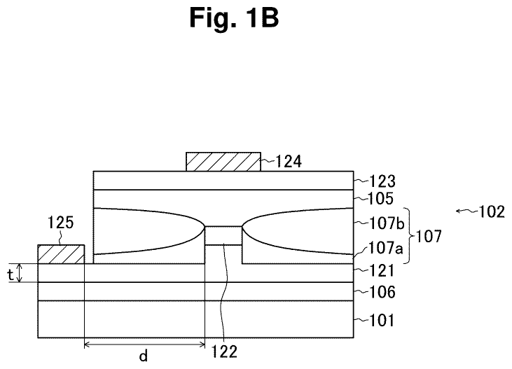

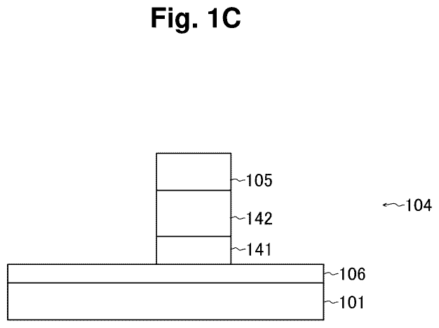

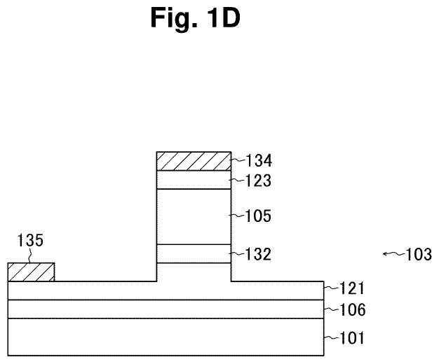

Hereinafter, a semiconductor device according to an embodiment of the present invention will be described with reference to FIGS. 1A, 1B, 1C, and 1D. The semiconductor device includes a substrate 101 made of semi-insulating InP, a first optical active element 102 formed on the substrate 101, and a second optical active element 103 formed on the substrate 101. An optical waveguide 104 is included between the first optical active element 102 and the second optical active element 103, functions as an electrical isolation portion between the first optical active element 102 and the second optical active element 103, and optically connects the first optical active element 102 and the second optical active element 103 with each other.

The substrate 101 can be made of, for example, InP that is given high resistance by doping it with Fe. Further, the substrate 101 can have a (001) plane of InP as a main surface. FIG. 1A illustrates a cross section parallel to a waveguide direction of light as a carrier wave. FIGS. 1B, 1C, and 1D illustrate cross sections perpendicular to the waveguide direction.

The first optical active element 102 includes a first lower semiconductor layer 121 made of p-type InP (for example, doping amount 5E18 cm⁻³) formed on the substrate 101, a first active layer 122 formed on the first lower semiconductor layer 121 and having a ridge waveguide structure, and an upper semiconductor layer 105 made of n-type InP formed on the first active layer 122. The first active layer 122 can be made of, for example, InGaAsP or InGaAlAs. In addition, the first active layer 122 can have a thickness of about 250 nm.

In addition, the first optical active element 102 includes a first n-electrode 124 formed on the upper semiconductor layer 105 and a first p-electrode 125 formed on the first lower semiconductor layer 121 in a region where the first active layer 122 is not formed. In this example, the first n-electrode 124 is formed on the upper semiconductor layer 105 via a contact layer 123. The contact layer 123 can be made of, for example, InGaAs into which a p-type impurity is introduced at a high concentration. The first optical active element 102 is a so-called vertical current injection type semiconductor laser that performs current injection into the first active layer 122 in a direction perpendicular to a plane of the substrate 101. For example, the first optical active element 102 can be a distributed feedback (DFB) laser including a diffraction grating on an upper surface, a lower surface, or a side surface of the first active layer 122. In this case, a length of the first optical active element 102 in the waveguide direction is a resonator length.

The second optical active element 103 includes a second active layer 132 formed on the first lower semiconductor layer 121 and having a ridge waveguide structure, and the upper semiconductor layer 105 formed on the second active layer 132. The second active layer 132 can be made of, for example, InGaAsP or InGaAlAs. In addition, the second active layer 132 can have a thickness of about 280 nm.

In addition, the second optical active element 103 includes a second n-electrode 134 formed on the upper semiconductor layer 105 and a second p-electrode 135 formed on the first lower semiconductor layer 121 in a region where the second active layer 132 is not formed. In this example, the second n-electrode 134 is formed on the upper semiconductor layer 105 via the contact layer 123. The second optical active element 103 is an electric field absorption type optical modulator (EA modulator).

In addition, the first active layer 122 and the second active layer 132 can have a multiple quantum well structure (MQW structure). The first active layer 122 and the second active layer 132 indicate portions including the MQW structure and the upper and lower optical confinement layers (SCH), and also function as cores of the waveguide structure.

The optical waveguide 104 includes a second lower semiconductor layer 141 made of semi-insulating or undoped InP, a third active layer 142 formed on the second lower semiconductor layer 141 and having a ridge waveguide structure, and the upper semiconductor layer 105 formed on the third active layer 142. The second lower semiconductor layer 141 is formed in a groove formed in the first lower semiconductor layer 121 in a region of the optical waveguide 104 between the first optical active element 102 and the second optical active element 103. Note that, in this example, the upper semiconductor layer 105 is commonly formed in the first optical active element 102, the second optical active element 103, and the optical waveguide 104.

The third active layer 142 functions as a core of the optical waveguide 104. In the optical waveguide 104, the second lower semiconductor layer 141 and the upper semiconductor layer 105 function as claddings. The third active layer 142 can be made of, for example, InGaAsP having a composition ratio of a band gap wavelength of 1.1 μm.

In this example, an etching stop layer 106 formed over the entire region on the substrate 101 is included. The first optical active element 102, the optical waveguide 104, and the second optical active element 103 are formed on the etching stop layer 106. As is well known, the etching stop layer 106 is made of a material different from those of the first lower semiconductor layer 121 and the second lower semiconductor layer 141.

The first lower semiconductor layer 121 in the region where the second active layer 132 is not formed is made thinner than the first lower semiconductor layer 121 in a region where the second active layer 132 is formed. An embedding layer 107 is formed on the first lower semiconductor layer 121 to embed the first active layer 122 is further included. In this example, the embedding layer 107 includes an n-type embedding layer 107a and a p-type embedding layer 107b. Note that the present invention is not limited thereto, and the embedding layer 107 can be made of semi-insulating InP having high resistance.

The first p-electrode 125 is formed at a position where the embedding layer 107 is removed, and the first lower semiconductor layer 121 where the first p-electrode 125 is formed (in a region where the first active layer 122 is not formed) has a thickness from 400 nm to 1000 nm. Further, the first p-electrode 125 is formed 2 μm to 20 μm away from the first active layer 122.

Next, the thickness of the first lower semiconductor layer 121 will be described. Resistivity p of p-type InP is 5.0E10 (Ωcm⁻³) when the doping amount is 5E18 (cm⁻³). As illustrated in FIGS. 1A and 1B, the thickness of the first lower semiconductor layer 121 in the region where the first p-electrode 125 is formed is t (μm), and the length of the first optical active element 102 in the waveguide direction is L (μm). A distance between the first p-electrode 125 and the first active layer 122 is d (μm). The distance between the first p-electrode 125 and the first active layer 122 can be set to an interval between the first p-electrode 125 and the first active layer 122 in a direction parallel to a surface of the substrate 101 (in plan view). A resistance value R (Ω) of the first lower semiconductor layer 121 between the first p-electrode 125 and the first active layer 122 can be expressed by “R=ρ×d/(L×t)” where the resistivity is ρ (Ωcm).

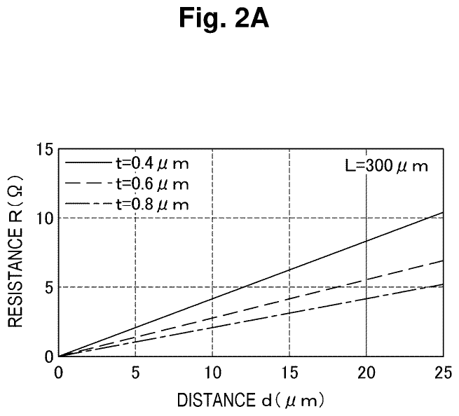

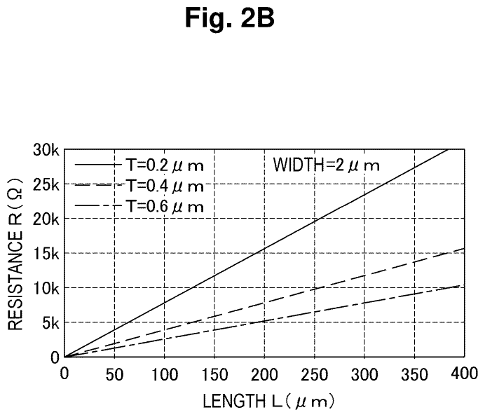

FIG. 2A illustrates calculation results of the resistance value R when the length L in the waveguide direction is 300 μm and the thickness t is 0.4 μm, 0.6 μm, and 0.8 μm. As shown in FIG. 2A, even in a general length 300 μm of the first optical active element 102 in the waveguide direction, when the thickness t of the first lower semiconductor layer 121 made of p-type InP is 0.4 μm (400 nm) and the distance d is 20 μm or less, it is possible to achieve a resistance value of 10Ω or less at which the first optical active element 102 can normally operate. As shown in FIG. 2A, from the viewpoint of reducing the resistance, the resistance of the first lower semiconductor layer 121 can be reduced as the first lower semiconductor layer is thicker than 400 nm. Note that the distance d between the first p-electrode 125 and the first active layer 122 is 2 μm or more due to the presence of the embedding layer 107 that embeds the first active layer 122.

However, the thickness of the first lower semiconductor layer 121 is limited. When the first lower semiconductor layer 121 is made too thick, the following problem occurs. In the semiconductor device according to the embodiment, as is well known, in the formation of the embedding layer 107, the first active layer 122 is patterned and formed to be a ridge shape (high-mesa shape), and the embedding layer 107 is grown on the first lower semiconductor layer 121 on both sides of the patterned first active layer 122 by crystal regrowth.

In such crystal regrowth, when the thickness of the first lower semiconductor layer 121 increases, a problem of abnormal growth occurs in which the thickness of the semiconductor layer growing at a regrowth interface abnormally increases. In order to suppress this problem, it is necessary to limit the thickness of the first lower semiconductor layer 121 to be regrown to 1000 nm or less. Therefore, it is important that the first lower semiconductor layer 121 has a thickness from 400 nm to 1000 nm.

For example, when the length (resonator length) in the waveguide direction is 300 μm, the thickness t is 800 nm, the distance is 8 μm, and the doping amount of the first lower semiconductor layer 121 is 5E18 (cm⁻³), the resistance value of the first lower semiconductor layer 121 between the first p-electrode 125 and the first active layer 122 is about 1.7Ω from the calculation result shown in FIG. 2A. This value is sufficiently smaller than the comparison of the resistance between the LD on the SI substrate and the LD on the n substrate described in Non Patent Literature 1. As described above, according to the embodiment, it can be considered that the influence on the optical output characteristics of the first optical active element 102 can be suppressed.

Furthermore, a thickness of a portion (an upper portion of the third active layer 142) of the upper semiconductor layer 105 formed in the optical waveguide 104 serving as the electrical isolation portion will be described. In order to perform electrical isolation between the first n-electrode 124 and the second n-electrode 134, it is necessary to secure a sufficient value of electric resistance therebetween. In general, the resistivity of n-type InP is lower than that of p-type InP, and thus by appropriately setting the thickness of this portion, more reliable electrical isolation can be achieved.

FIG. 2B shows calculation results of the resistance value of the upper semiconductor layer 105 on the third active layer 142 when the waveguide width of the optical waveguide 104 having a high-mesa structure is 2 μm and a thickness of a portion of the upper semiconductor layer 105 formed in the optical waveguide 104 (the upper portion of the third active layer 142) is 0.2 μm, 0.4 μm, and 0.6 μm. For example, when the above-described thickness is 0.6 μm (600 nm) and the length of the optical waveguide 104 in the waveguide direction is 200 μm or more, a sufficient resistance value of 5 k (2 or more is obtained, and electrical isolation between the first n-electrode 124 and the second n-electrode 134 can be achieved.

It goes without saying that forming the first p-electrode 125 2 μm to 20 μm away from the first active layer 122, setting the length of the optical waveguide 104 to 200 μm or more, and setting the thickness of the portion of the upper semiconductor layer 105 formed on the third active layer 142 to 600 nm or less can be used in combination.

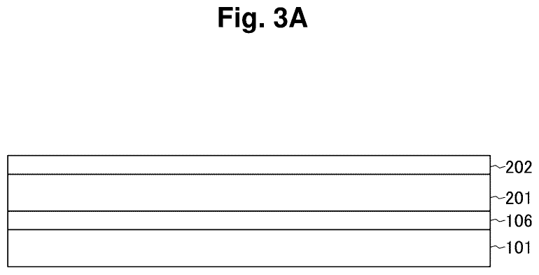

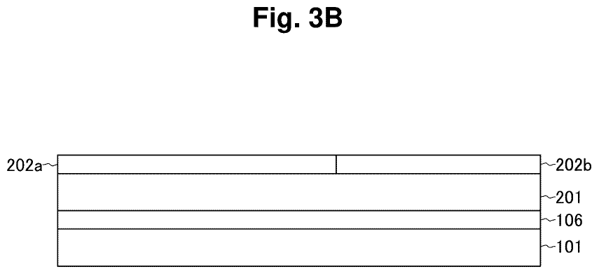

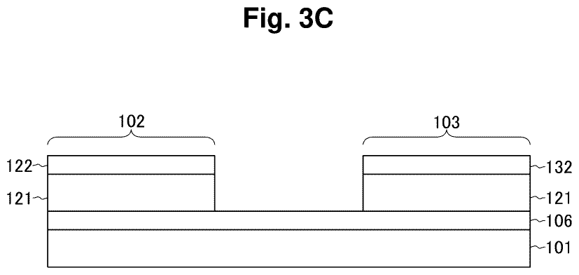

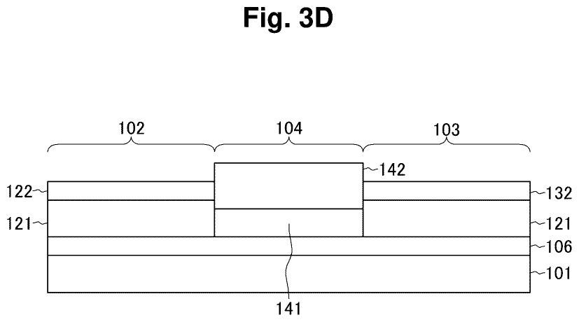

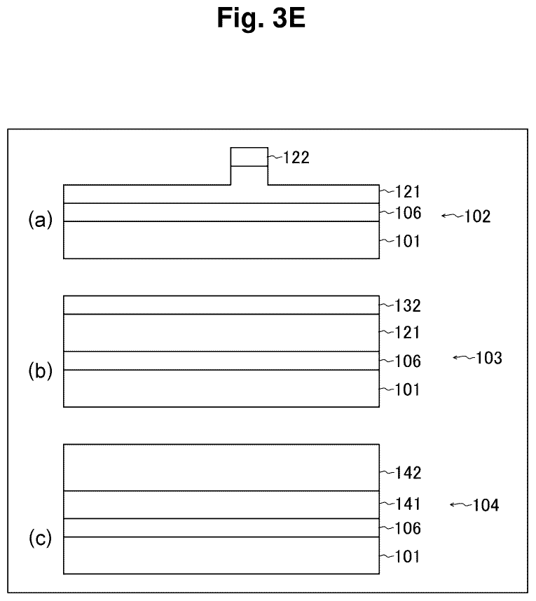

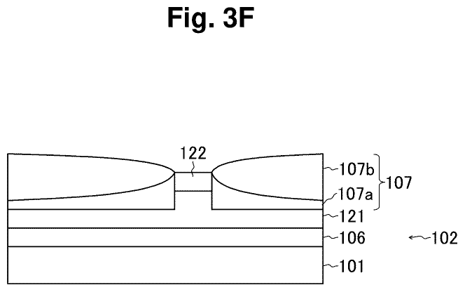

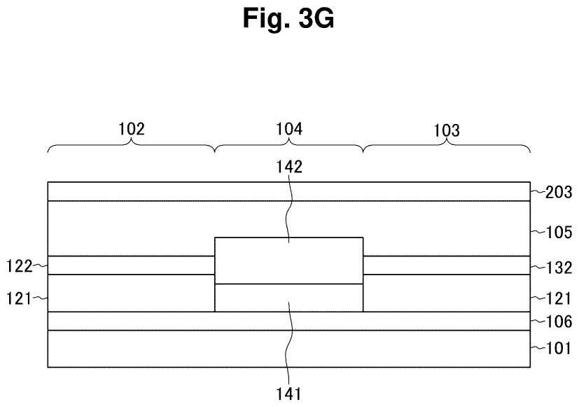

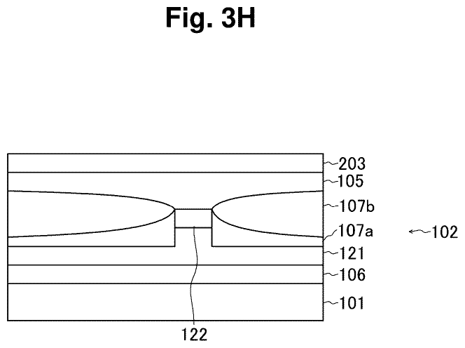

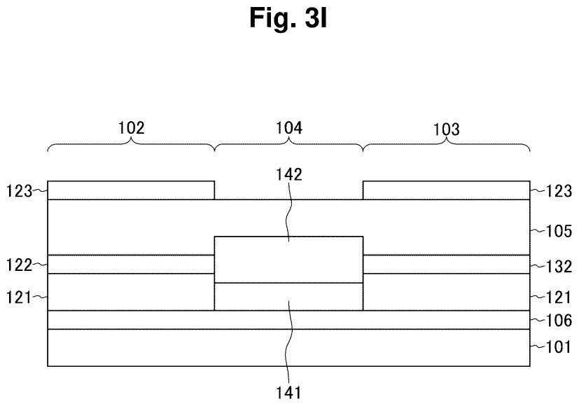

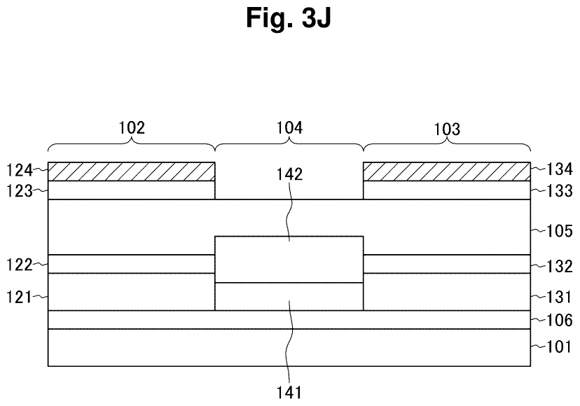

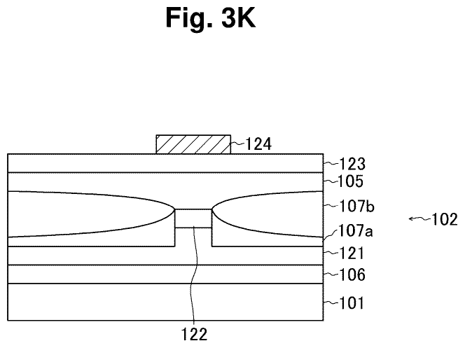

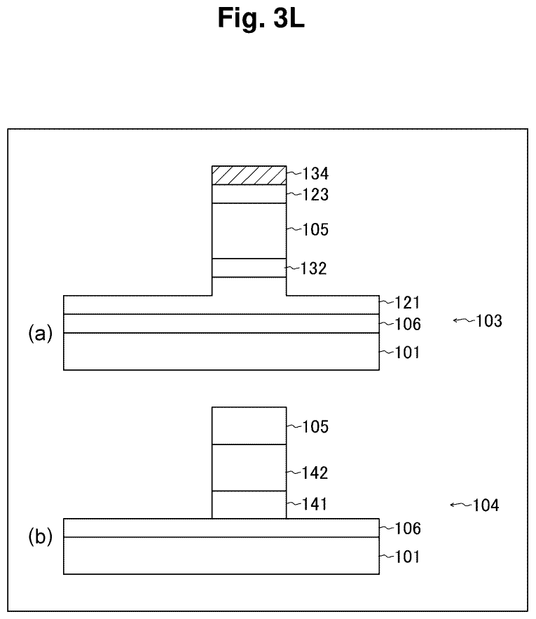

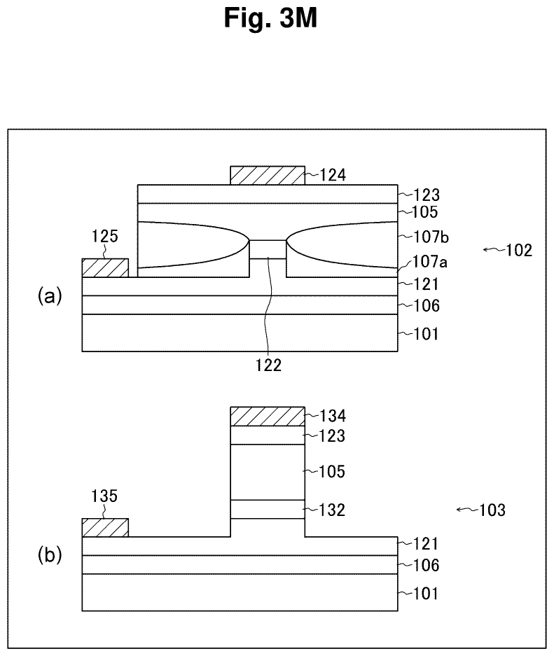

Next, a method for manufacturing a semiconductor device according to the embodiment of the present invention will be described with reference to FIGS. 3A to 3M.

First, as illustrated in FIG. 3A, undoped InGaAsP is crystal-grown on the substrate 101 to form the etching stop layer 106 having a thickness of 10 nm. Subsequently, the p-type InP (doping amount 5E18) is crystal-grown to form an InP layer 201 having a thickness of 1000 nm. Subsequently, an active layer 202 formed of the InGaAsP and having a thickness of 250 nm is formed (crystal growth). Crystal growth of each semiconductor layer can be performed by, for example, a well-known metal organic chemical vapor deposition method. The same applies to crystal growth of each semiconductor layer described below.

Next, by removing the active layer 202 in the region to be the second optical active element 103, as illustrated in FIG. 3B, an active layer 202a is formed, and an active layer 202b, for example, having a thickness of 280 nm is formed (crystal growth) by the InGaAsP at the removed portion, and the active layer 202a and the active layer 202b are butt-joined in the waveguide direction (a butt joint process). The active layer 202a and the active layer 202b can have a multiple quantum well structure (MQW structure). In this case, the above thicknesses are assumed to include the upper and lower optical confinement layers (SCH) of the MQW structure.

Next, predetermined regions of the active layer 202a, the active layer 202b, and the InP layer 201 are removed by etching processing using a mask pattern (not illustrated) formed by a known photolithography technique, so that the first lower semiconductor layer 121 and the first active layer 122 of the first optical active element 102 are formed, and the first lower semiconductor layer 121 of the second optical active element 103 and the second optical active element 103 are formed, as illustrated in FIG. 3C.

A region between the first optical active element 102 and the second optical active element 103 is a region forming the optical waveguide 104. In the etching processing of the InP layer 201, selective wet etching using the etching stop layer 106 can be used. For example, by using HCl and H₃PO₄ as an etching solution, the etching stop layer 106 made of InGaAsP is not etched, and the layer made of InP can be selectively etched away.

Next, as illustrated in FIG. 3D, the second lower semiconductor layer 141 and the third active layer 142 of the optical waveguide 104 are formed by crystal growth. The second lower semiconductor layer 141 can be formed to have a thickness of about 900 nm, and the third active layer 142 can be formed to have a thickness of about 400 nm.

Next, as illustrated in FIG. 3E, a waveguide of the first optical active element 102 is formed by etching processing using a mask pattern (not illustrated) formed by a known photolithography technique. The mask pattern has a shape that covers the entire region of the second optical active element 103 and the optical waveguide 104, and patterning is not performed on the regions of the second optical active element 103 and the optical waveguide 104.

In the processing of the first optical active element 102, the first lower semiconductor layers 121 on both sides of the ridge waveguide structure of the first active layer 122 are thinned. A region where the first lower semiconductor layer 121 is thinned is a region where the first p-electrode 125 is formed, and is thinned with a thickness of 400 nm as a limit as described above.

The first optical active element 102 has an optical waveguide structure with the first active layer 122 as the core, and when a semiconductor layer highly doped with a conductive impurity (p-type impurity) is present near the first active layer 122 in a cross-section in the waveguide direction, a waveguide loss occurs as is well known. In this case, the first lower semiconductor layer 121 is a semiconductor layer highly doped with the impurity. For this reason, when only the first active layer 122 has a ridge shape, a semiconductor layer highly doped with the impurity is present in the vicinity of both side surfaces in addition to immediately below the first active layer 122 of the ridge shape. On the other hand, by thinning the first lower semiconductor layers 121 on both sides of the ridge waveguide structure of the first active layer 122, the semiconductor layer highly doped with the impurity in the region other than the region immediately below the first active layer 122 can be separated from the first active layer 122, and the waveguide loss can be suppressed.

Next, as illustrated in FIG. 3F, InP is crystal-regrown on the first lower semiconductor layer 121 left on both sides of the ridge waveguide structure, so that the ridge waveguide structure is embedded with the embedding layer 107. For example, first, a selective growth mask (not illustrated) made of silicon oxide or the like is formed on the first active layer 122. Next, n-type InP is regrown to form the n-type embedding layer 107a. Subsequently, p-type InP is grown to form the p-type embedding layer 107b, and the embedding layer 107 including the n-type embedding layer 107a and the p-type embedding layer 107b is formed.

Next, as illustrated in FIGS. 3G and 3H, n-type InP is crystal-grown to form the upper semiconductor layer 105, and InGaAsP or InGaAs is crystal-grown to form the contact layer 203.

Next, the contact layer 203 in the region of the optical waveguide 104 is removed by etching processing using a mask pattern (not illustrated) formed by a known photolithography technique, so that the contact layer 123 is formed on the first optical active element 102 and the second optical active element 103 as illustrated in FIG. 3I. The contact layer 123 on the first optical active element 102 and the contact layer 123 on the second optical active element 103 are formed in a state of being electrically separated from each other in a plane direction parallel to the surface of the upper semiconductor layer 105.

Next, as illustrated in FIGS. 3J and 3K, the first n-electrode 124 is formed on the contact layer 123 on the first optical active element 102, and the second n-electrode 134 is formed on the contact layer 123 on the second optical active element 103. In addition, as illustrated in FIG. 3L, the second optical active element 103 and the optical waveguide 104 are patterned into a high-mesa structure. Note that, similarly to the region of the first optical active element 102 described above, in the second optical active element 103, the first lower semiconductor layers 121 on both sides of the waveguide structure of the high-mesa are thinned.

Next, as illustrated in FIG. 3M, the first p-electrode 125 electrically connected to the first lower semiconductor layer 121 of the first optical active element 102 is formed, and the second p-electrode 135 electrically connected to the first lower semiconductor layer 121 of the second optical active element 103 is formed. In the formation of the first p-electrode 125, the contact layer 123, the upper semiconductor layer 105, and the embedding layer 107 in the region forming the first p-electrode 125 are patterned and removed by a known lithography technique and etching technique to expose an upper surface of the first lower semiconductor layer 121. Thereafter, the first p-electrode 125 is formed on the exposed upper surface of the first lower semiconductor layer 121.

As described above, according to the present invention, the thickness of the region where the first p-electrode of the first lower semiconductor layer made of p-type InP below the first active layer is formed is from 400 nm to 1000 nm, and thus the two monolithically integrated optical active elements can be driven by respective different methods without causing deterioration in optical output characteristics and optical modulation characteristics.

Some or all of the embodiments described above are also described as the following supplementary notes, but are not limited thereto.

### [Supplementary Note 1]

A semiconductor device including a substrate made of semi-insulating InP, a first optical active element formed on the substrate, a second optical active element formed on the substrate, and an optical waveguide disposed between the first optical active element and the second optical active element, functioning as an electrical isolation portion between the first optical active element and the second optical active element, and optically connecting the first optical active element and the second optical active element with each other, wherein the first optical active element includes a first lower semiconductor layer made of p-type InP formed on the substrate, a first active layer formed on the first lower semiconductor layer and having a ridge waveguide structure, an upper semiconductor layer made of n-type InP formed on the first active layer, a first n-electrode formed on the upper semiconductor layer, and a first p-electrode formed on the first lower semiconductor layer in a region where the first active layer is not formed, the second optical active element includes a second active layer formed on the first lower semiconductor layer and having a ridge waveguide structure, the upper semiconductor layer formed on the second active layer, a second n-electrode formed on the upper semiconductor layer, and a second p-electrode formed on the first lower semiconductor layer in a region where the second active layer is not formed, the optical waveguide includes a second lower semiconductor layer made of semi-insulating or undoped InP formed in a groove formed in the first lower semiconductor layer in the region of the optical waveguide, a third active layer formed on the second lower semiconductor layer and having a ridge waveguide structure, and the upper semiconductor layer formed on the third active layer, the first lower semiconductor layer in a region where the second active layer is not formed is made thinner than the first lower semiconductor layer in a region where the second active layer is formed, an embedding layer embedding the first active layer is formed on the first lower semiconductor layer, the first p-electrode is formed at a position where the embedding layer is removed, and the first lower semiconductor layer where the first p-electrode is formed has a thickness from 400 nm to 1000 nm.

### [Supplementary Note 2]

The semiconductor device according to Supplementary note 1, wherein the first p-electrode is formed 2 μm to 20 μm away from the first active layer.

### [Supplementary Note 3]

The semiconductor device according to Supplementary note 1 or 2, wherein a length of the optical waveguide is 200 μm or more, and a thickness of a portion of the upper semiconductor layer formed on the third active layer is 600 nm or less.

### [Supplementary Note 4]

The semiconductor device according to any one of Supplementary notes 1 to 3, further including an etching stop layer formed over the entire region on the substrate, wherein the first optical active element, the optical waveguide, and the second optical active element are formed on the etching stop layer.

Note that the present invention is not limited to the embodiments described above, and it is obvious that many modifications and combinations can be made by those skilled in the art within the technical idea of the present invention.

Reference Signs List

| | |
|---|---|
| 101 | Substrate |
| 102 | First optical active element |
| 103 | Second optical active element |
| 104 | Optical waveguide |
| 105 | Upper semiconductor layer |
| 106 | Etching stop layer |
| 107 | Embedding layer |
| 107a | n-type embedding layer |
| 107b | p-type embedding layer |
| 121 | First lower semiconductor layer |
| 122 | First active layer |
| 123 | Contact layer |
| 124 | First n-electrode |
| 125 | First p-electrode |
| 132 | Second active layer |
| 134 | Second n-electrode |
| 135 | Second p-electrode |
| 141 | Second lower semiconductor layer |
| 142 | Third active layer |

1-4. (canceled)

5. A semiconductor device comprising:
a substrate made of semi-insulating InP;
a first lower semiconductor layer made of p-type InP on the substrate;
a first optical active element on a first region of the substrate;
a second optical active element on a second region of the substrate; and
an optical waveguide disposed between the first optical active element and the second optical active element, configured to function as an electrical isolation portion between the first optical active element and the second optical active element, and configured to optically connect the first optical active element and the second optical active element with each other, wherein
the first lower semiconductor layer includes a groove in a region where the optical waveguide is disposed,
the first optical active element includes the first lower semiconductor layer on the first region of the substrate, a first active layer on the first lower semiconductor layer and having a ridge waveguide structure, an upper semiconductor layer made of n-type InP on the first active layer, a first n-electrode on the upper semiconductor layer, and a first p-electrode on the first lower semiconductor layer in a region where the first active layer is not present,
the second optical active element includes the first lower semiconductor layer on the second region of the substrate, a second active layer on the first lower semiconductor layer and having a ridge waveguide structure, the upper semiconductor layer on the second active layer, a second n-electrode on the upper semiconductor layer, and a second p-electrode on the first lower semiconductor layer in a region where the second active layer is not present,
the optical waveguide includes a second lower semiconductor layer made of semi-insulating or undoped InP in the groove of the first lower semiconductor layer, a third active layer on the second lower semiconductor layer and having a ridge waveguide structure, and the upper semiconductor layer on the third active layer,
the first optical active element further includes an embedding layer on the first lower semiconductor layer and embedding the first active layer,
the first p-electrode is at a position where the embedding layer is not present, and
the first lower semiconductor layer where the first p-electrode has a thickness from 400 nm to 1000 nm.

6. The semiconductor device according to claim 5, wherein
the first lower semiconductor layer in a region where the second active layer is not present is thinner than the first lower semiconductor layer in a region where the second active layer is present.

7. The semiconductor device according to claim 5, wherein the first p-electrode is 2 μm to 20 μm away from the first active layer.

8. The semiconductor device according to claim 6, wherein the first p-electrode is 2 μm to 20 μm away from the first active layer.

9. The semiconductor device according to claim 5, wherein
a length of the optical waveguide is 200 μm or more, and
a thickness of a portion of the upper semiconductor layer on the third active layer is 600 nm or less.

10. The semiconductor device according to claim 6, wherein
a length of the optical waveguide is 200 μm or more, and
a thickness of a portion of the upper semiconductor layer on the third active layer is 600 nm or less.

11. The semiconductor device according to claim 5, further comprising an etching stop layer over the entire region on the substrate, wherein
the first optical active element, the optical waveguide, and the second optical active element are on the etching stop layer.

12. The semiconductor device according to claim 6, further comprising an etching stop layer over the entire region on the substrate, wherein
the first optical active element, the optical waveguide, and the second optical active element are on the etching stop layer.

13. The semiconductor device according to claim 7, further comprising an etching stop layer over the entire region on the substrate, wherein
the first optical active element, the optical waveguide, and the second optical active element are on the etching stop layer.

14. The semiconductor device according to claim 8, further comprising an etching stop layer over the entire region on the substrate, wherein
the first optical active element, the optical waveguide, and the second optical active element are on the etching stop layer.

15. The semiconductor device according to claim 9, further comprising an etching stop layer over the entire region on the substrate, wherein
the first optical active element, the optical waveguide, and the second optical active element are on the etching stop layer.

16. The semiconductor device according to claim 10, further comprising an etching stop layer over the entire region on the substrate, wherein
the first optical active element, the optical waveguide, and the second optical active element are on the etching stop layer.

17. A method for manufacturing a semiconductor device comprising:
crystal-growing an etching stop layer on a substrate made of semi-insulating InP;
crystal-growing a p-type InP layer having a thickness of 1000 nm on the etching stop layer;
crystal-growing a first active layer on the p-type InP layer;
removing the first active layer in a region to be a second optical active element;
crystal-growing a second active layer at the removed portion to butt-join the first active layer and the second active layer in a waveguide direction;
removing predetermined regions of the first active layer, the second active layer, and the p-type InP layer by etching processing using selective wet etching with the etching stop layer to form a first optical active element and a second optical active element with a region between them for an optical waveguide;
crystal-growing a second lower semiconductor layer made of semi-insulating or undoped InP and a third active layer in the region for the optical waveguide;
etching the first optical active element to thin p-type InP layers on both sides of a ridge waveguide structure of the first active layer, wherein the p-type InP layer is thinned with a thickness from 400 nm to 1000 nm as a limit;
crystal-regrowing InP on the thinned p-type InP layers to embed the ridge waveguide structure with an embedding layer;
crystal-growing an upper semiconductor layer made of n-type InP and a contact layer; and
forming electrodes including a first p-electrode on the thinned p-type InP layer where the embedding layer is removed.

18. The method according to claim 17, wherein the selective wet etching uses HCl and H₃PO₄ as an etching solution to selectively etch InP while not etching the etching stop layer made of InGaAsP.

19. The method according to claim 17, wherein the crystal-regrowing InP to embed the ridge waveguide structure comprises:
forming a selective growth mask made of silicon oxide on the first active layer;
regrowing n-type InP to form an n-type embedding layer; and
growing p-type InP to form a p-type embedding layer.

20. A semiconductor device comprising:
a substrate made of semi-insulating InP;
a first optical active element and a second optical active element on the substrate;
an optical waveguide between the first optical active element and the second optical active element, the optical waveguide providing electrical isolation between the first optical active element and the second optical active element while optically connecting the first optical active element and the second optical active element;
a first lower semiconductor layer made of p-type InP, wherein a portion of the first lower semiconductor layer under the first optical active element has a thickness from 400 nm to 1000 nm to enable single-phase driving of the first optical active element; and
a second lower semiconductor layer made of semi-insulating or undoped InP under the optical waveguide, wherein the second lower semiconductor layer electrically isolates the first optical active element from the second optical active element to enable differential driving of the second optical active element.

21. The semiconductor device according to claim 20, wherein the first optical active element comprises a distributed feedback laser and the second optical active element comprises an electroabsorption modulator.

22. The semiconductor device according to claim 20, wherein the first optical active element includes a first active layer having a ridge waveguide structure and an embedding layer embedding the first active layer, and the first lower semiconductor layer has the thickness from 400 nm to 1000 nm in a region where a first p-electrode is present and the embedding layer is not present.

23. The semiconductor device according to claim 20, wherein the optical waveguide has a length of 200 μm or more and includes an upper semiconductor layer made of n-type InP having a thickness of 600 nm or less on a third active layer to provide sufficient electrical resistance for the electrical isolation.
